(19) United States
(12) Patent Application Publication
(10) Pub. No.: US 2004/0084211 A1
(43) Pub. Date: May 6, 2004

(54) Z-axis packaging for electronic device and method for making same

(75) Inventor: Robert T. Fayfield, St. Louis Park, MN (US)

Correspondence Address: ALTERA LAW GROUP, LLC, 6500 CITY WEST PARKWAY, SUITE 100, MINNEAPOLIS, MN, 55344-7704, US

(73) Assignee: Sensonix, Inc., Plymouth, MN

(21) Appl. No.: 10/284,892

(22) Filed: Oct. 30, 2002

(51) Int. Cl. H05K 1/11

(52) U.S. Cl. 174/261

(57) ABSTRACT

A z-axis package for an electronic device and a method for making the z-axis packaging for the electronic device. The z-axis package is inexpensive to manufacture and can be assembled with automated surface mount equipment by the end user.

### BACKGROUND OF THE INVENTION

1. Field of the Invention

This invention relates in general to semiconductor mounting packages, and more particularly to z-axis packaging for an electronic device and a method for making the z-axis packaging for the electronic device.

2. Description of Related Art

Electronic packages are used to house a wide variety of electronic devices. For example, integrated circuit semiconductor devices are fabricated on wafers in such a manner as to generate many discrete output semiconductor device chips. Each of these discrete semiconductor device chips forms an integrated circuit semiconductor device die that must be packaged in order to be utilized within a computer system.

One type of package encapsulates the semiconductor device die in a plastic package and bonds the die to a lead frame paddle. The lead frame's leads are then connected to pads on the semiconductor device die with the unit being encapsulated in a suitable plastic. This plastic encapsulated semiconductor device chip then undergoes a trim and form operation that separates the interconnected packages on the lead frame strips into individual entities and bends the lead package. This is the traditional and most recognized form of packaged IC chip and utilizes a highly automated manufacturing technology.

Some electronic devices, such as sensors, often require vertical or z-axis mounting packages. For example, a miniature magnetic compass includes a magnetic sensor chip that is sensitive to magnetic fields lying in the plane of the chip. The magnetic compass sensor must sense magnetic fields that are perpendicular to the surface on which the chip is mounted. In effect, the chip needs to be oriented in the vertical direction. In this case, the sensing element should be oriented normal to the surface of the earth. However, other types of devices may also require z-axis mounting packages.

Nevertheless, existing z-axis packages are either expensive to manufacture or cannot be assembled with automated surface mount equipment by the end user. For example, existing leaded z-axis packages are small and cheap to manufacture but are difficult to attach to the final printed circuit board. Assembling leaded parts is often a manual operation and causes inaccuracy of the angle of the z-axis component of the package, i.e., the package leans off the normal orientation by many degrees.

Another example of a z-axis package is a surface mountable z-axis package. Because the surface mountable z-axis package has flat leads on the bottom, it is easy to assemble onto the final printed circuit board. However, the package assembly process requires multiple complex steps and fixtures because the package is composed of two separate miniature substrates. A first separate substrate includes surface mount pads on the bottom to attach to the final assembly.

A second vertical substrate is used to support the silicon die. These two miniature substrates are attached to each other using butt solder joints that are difficult to automate.

Thus, existing z-axis packages do not satisfy the requirements for providing a highly orthogonal package relative to the mounting surface; i.e., precise z-axis alignment, being inexpensive to manufacture by using existing equipment and process steps, enabling automated surface mount assembly to the next level printed circuit board, meeting the small size constraint of consumer applications such as cell phone compasses, and complying with the limitation entirely non-magnetic materials composition.

It can be seen then that there is a need for z-axis packaging for an electronic device and a method for making the z-axis packaging for the electronic device that is inexpensive to manufacture and which can be assembled with automated surface mount equipment by the end user.

### SUMMARY OF THE INVENTION

To overcome the limitations in the prior art described above, and to overcome other limitations that will become apparent upon reading and understanding the present specification, the present invention discloses z-axis packaging for an electronic device and a method for making the z-axis packaging for the electronic device.

The present invention solves the above-described problems by redistributing planar interconnection on a standard component (bonding pads on a silicon die for example) to an orthogonal interconnection scheme in the package.

A method in accordance with the principles of the present invention includes filling via holes in a substrate, attaching at least one die to the substrate, providing encapsulation to at least a portion of at least one side of the substrate and processing the substrate to form individual z-axis device packages having edge signal contacts at the via holes at a connection side of the z-axis package for providing connections to an x-y platform.

In another embodiment of the present invention a z-axis electronic device package is provided. The z-axis electronic device package includes a mounting surface plane formed by a substrate and encapsulation applied to at least a portion of at least one side of the substrate, the mounting surface including connections from the substrate, the connections being formed in the mounting surface plane, the mounting surface plane being orthogonal to a plane of the substrate, the substrate including at least one die coupled to the substrate orthogonal to the mounting surface plane.

In another embodiment of the present invention another z-axis electronic device package is provided. The z-axis electronic device package includes a mounting surface plane formed by a substrate and encapsulation applied to at least a portion of at least one side of the substrate, the mounting surface being coupled to defined extended terminals for providing a leveling support structure during soldering.

In another embodiment of the present invention another z-axis electronic device package is provided. The z-axis electronic device package includes a mounting surface plane formed by a substrate and encapsulation applied to at least a portion of at least one side of the substrate, the mounting surface being coupled to split terminals for providing a leveling support structure during soldering.

In another embodiment of the present invention a method for forming an electronic device package is provided, wherein the method includes filling via holes in a substrate, attaching at least one die to the substrate, providing encapsulation to at least a portion of at least one side of the substrate and processing the substrate to form at least one individual z-axis device package having edge signal contacts at the via holes at a connection side of the z-axis package and mounting the z-axis device package to a circuit board forming an x-y plane.

In another embodiment of the present invention an electronic device package is provided. The electronic device package includes a z-axis electronic package, the z-axis package including a mounting surface plane formed by a substrate and encapsulation applied to at least a portion of at least one side of the substrate, the mounting surface including connections from the substrate, the connections being formed in the mounting surface plane, the mounting surface plane being orthogonal to a plane of the substrate, the substrate including at least one die coupled to the substrate orthogonal to the mounting surface plane and a circuit board having at least one electronic device thereon, wherein the z-axis electronic package is mounted to the circuit board at the mounting surface plane of the z-axis package for maintaining the at least one die orthogonal to a plane formed by the circuit board.

In another embodiment of the present invention a method for forming a z-axis electronic device package is provided. The method includes filling via holes in a substrate, attaching at least one die to the substrate, providing encapsulation to at least a portion of at least one side of the substrate and processing the substrate to form individual z-axis device packages having a width/height ratio that is selected to be substantially equal to one and having edge signal contacts at the via holes at a connection side of the z-axis package for providing connections to an x-y platform, wherein the width/height ratio of substantially one provides stability to the package.

In another embodiment of the present invention a z-axis electronic device package is provided. The z-axis electronic device package includes a mounting surface plane formed by a substrate and encapsulation applied to at least a portion of at least one side of the substrate, the mounting surface including connections from the substrate, the connections being formed in the mounting surface plane, the mounting surface plane being orthogonal to a plane of the substrate, the substrate including at least one die coupled to the substrate orthogonal to the mounting surface plane, wherein the substrate and encapsulation form a device having a width/height ratio that is selected to be substantially equal to one, the width/height ratio of substantially one providing stability to the package.

These and various other advantages and features of novelty which characterize the invention are pointed out with particularity in the claims annexed hereto and form a part hereof. However, for a better understanding of the invention, its advantages, and the objects obtained by its use, reference should be made to the drawings which form a further part hereof, and to accompanying descriptive matter, in which there are illustrated and described specific examples of an apparatus in accordance with the invention.

### BRIEF DESCRIPTION OF THE DRAWINGS

Referring now to the drawings in which like reference numbers represent corresponding parts throughout:

FIG. 1 illustrates one example of an existing z-axis package;

FIG. 2 illustrates a second example of a z-axis package;

FIG. 3 illustrates a flat patterned substrate that is used as the starting material for a z-axis package according to the present invention;

FIG. 4 illustrates the flat patterned substrate with the via holes filled;

FIG. 5 illustrates the flat patterned substrate with dies attached thereto;

FIG. 6 illustrates the completed substrate being molded or cast with a liquid compound;

FIG. 7 illustrates the molded package after singulation;

FIG. 8 illustrates a completed z-axis package after processing;

FIG. 9 illustrates the final z-axis package according to the present invention;

FIG. 10 illustrates a z-axis package having a width/height ratio that is greater than one;

FIGS. 11 and 12 show the z-axis packages according to the present invention wherein the package has a width/height ratio that is substantially equal to one thereby providing stability to the package;

FIG. 13 illustrates a package having solderable terminals offset from package center and adjacent the package encapsulation material;

FIG. 14 is an illustration of the attachment of the conventional package;

FIG. 15 illustrates a z-axis package according to the present invention with defined extended terminals to act as leveling support structure during soldering;

FIG. 16 illustrates a z-axis package according to the present invention with split terminals to act as leveling support structure during soldering; and

FIGS. 17a-b illustrate a module using a z-axis package according to the present invention.

### DETAILED DESCRIPTION OF THE INVENTION

In the following description of the exemplary embodiment, reference is made to the accompanying drawings which form a part hereof, and in which is shown by way of illustration the specific embodiment in which the invention may be practiced. It is to be understood that other embodiments may be utilized as structural changes may be made without departing from the scope of the present invention.

The present invention provides z-axis packaging for an electronic device and a method for making the z-axis packaging for the electronic device that is inexpensive to manufacture and which can be assembled with automated surface mount equipment by the end user. Planar interconnections on a standard component (bonding pads on a silicon die for example) are redistributed to an orthogonal interconnection scheme in the package.

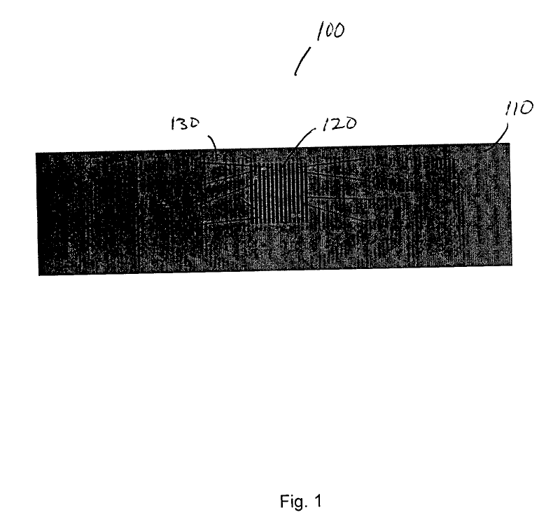

FIG. 1 illustrates one example of an existing z-axis package. Existing z-axis packages are either expensive to manufacture or cannot be assembled with automated surface mount equipment by the end user. An example of each is shown below. The z-axis package of FIG. 1 shows a leaded package 100. FIG. 1 illustrates a flat patterned substrate 110 that is used as the starting material. A die 120, which may represent a sensor for example, is wirebonded to the substrate 110. Leads 130 are attached to the substrate. The leaded package 100 illustrated in FIG. 1 is small and cheap to manufacture, but is difficult to attach to the final printed circuit board in its vertical orientation. Assembling leaded parts is often a manual operation and causes inaccuracy of the angle of the z-axis component of the package—in other words it leans off the normal orientation by many degrees.

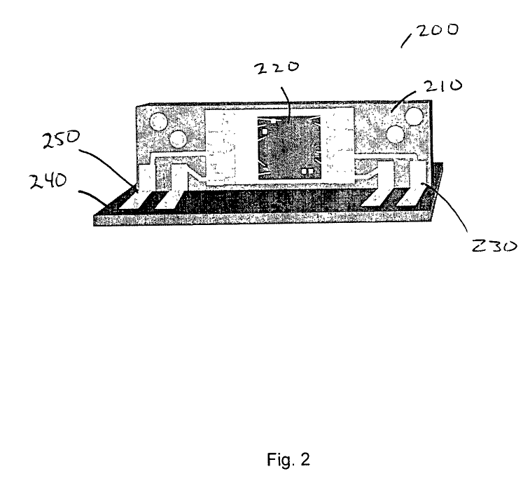

FIG. 2 illustrates a second example of a z-axis package. The z-axis package of FIG. 2 is a surface mountable z-axis package 200 (shown without encapsulation). Again, FIG. 2 illustrates a flat patterned substrate 210 that is used as the starting material. A die 220 is wirebonded to the substrate 210. The surface mountable z-axis package 200 has flat surface mount leads or pads 230 on the bottom thereby making it easy to assemble onto the final printed circuit board 240. However, the surface mountable z-axis package 200 assembly process requires multiple complex steps and fixtures. This is because the package is composed of two separate miniature substrates 210, 240—one with surface mount pads 230 on its bottom to attach to the second substrate 240 and the second substrate 240 to support the first substrate 210. These two miniature substrates 210, 240 are attached to each other using butt solder joints 250 that are difficult to automate.

In contrast to existing z-axis packages, the present invention provides a z-axis package that is both simple to manufacture and allows automated attachment to a higher-level printed circuit board. Planar interconnection on a standard component (bonding pads on a silicon die for example) are redistributed to an orthogonal interconnection scheme in the package.

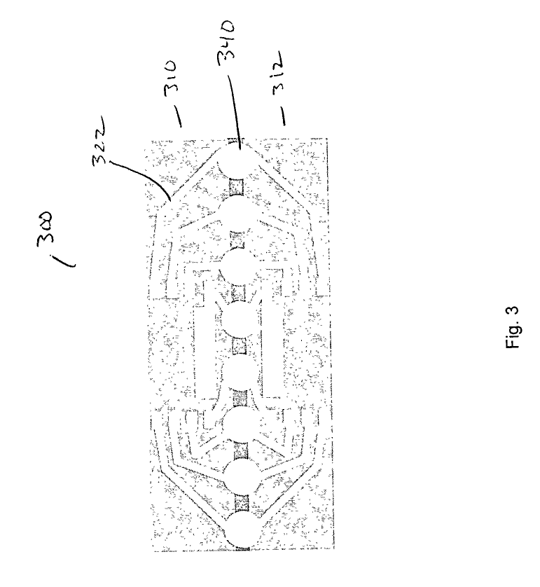

FIGS. 3-8 illustrate the process for making a z-axis package according to the present invention. FIG. 3 illustrates a flat patterned substrate 300 that is used as the starting material for a z-axis package according to the present invention. For purposes of clarity, the z-axis package of FIG. 3 shows only two packages 310, 312 on the substrate 300. However, in reality there would be dozens or even hundreds of packages on a single substrate. The flat patterned substrate 300 could be an epoxy based substrate (e.g., FR4), a ceramic substrate (e.g., LTCC or thick film ceramic), a laminate substrate, etc. However, those skilled in the will recognize that the present invention is not meant to be limited to any particular type of substrate and that other substrates may be utilized without departing from the scope of the present invention.

In the preferred embodiment of the present invention, the metal patterns 322 are both wire bondable so as to connect with the die (not shown) and solderable so as to connect with the higher-level printed circuit board assembly (not shown). A gold/nickel/copper stack may be used for most applications. However, if the package is to be used in a low field magnetic sensing applications, then the nickel underneath the gold with cause problems to the magnetic sensitivity. In this case, another surface metallization stack must be used. Two options that work with epoxy substrates are immersion silver/copper and gold/palladium/copper. The starting substrate must also have plated via through holes 340. The via holes 340 form the edge contacts on the z-axis package once processing has been completed. Normally, these can be the same metallization as the metal lines 322 on the package. However, for better solderability, these plated holes 340 can be terminated, for example, with a hot air solder leveling process (HASL) using a selective silver/HASL process.

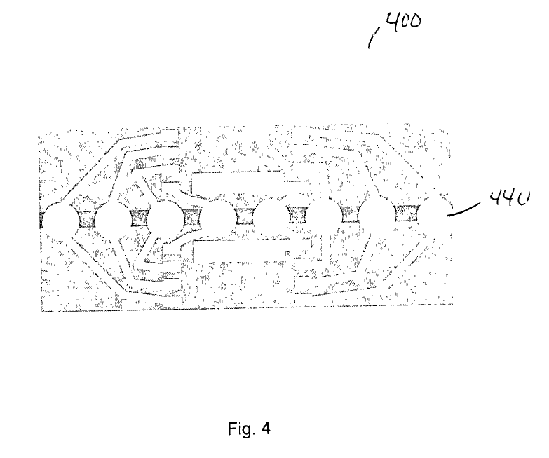

FIG. 4 illustrates the flat patterned substrate 400 with the via holes 440 filled. After the die(s) (not shown) are placed and wirebonded, the package will be encapsulated by casting with a liquid compound or transfer molding. In either case, the molding compound must be blocked from flowing through these via holes 440. Normally, the vias 440 could be tented with solder mask. However, according to the present invention, the vias 440 are too large and cannot be tented. Therefore, the vias 440 must be filled or blocked. This can be done with a mask or tape. Alternatively, as illustrated in FIG. 4, the vias 440 can be filled with solder and reflowed. This can be done be stencil printing or solder deposition.

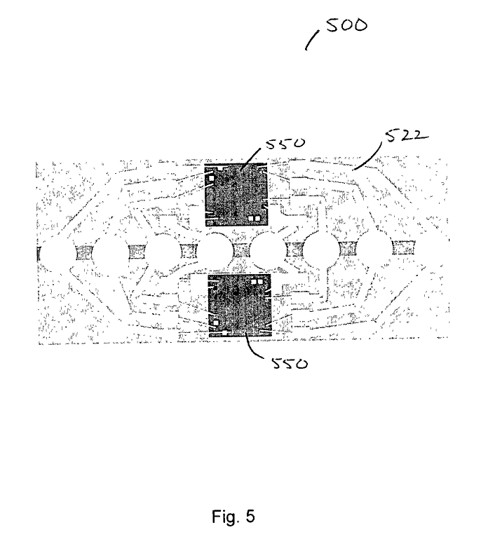

FIG. 5 illustrates the flat patterned substrate 500 with dies 550 attached thereto. The dies 550 are wirebonded to the metal lead lines 522 of the substrate 500. Alternatively, the die 550 may be flip chip/bumped die attached rather than wirebonded. Each of the steps for attaching the dies 550 to the substrate 500 can be easily automated.

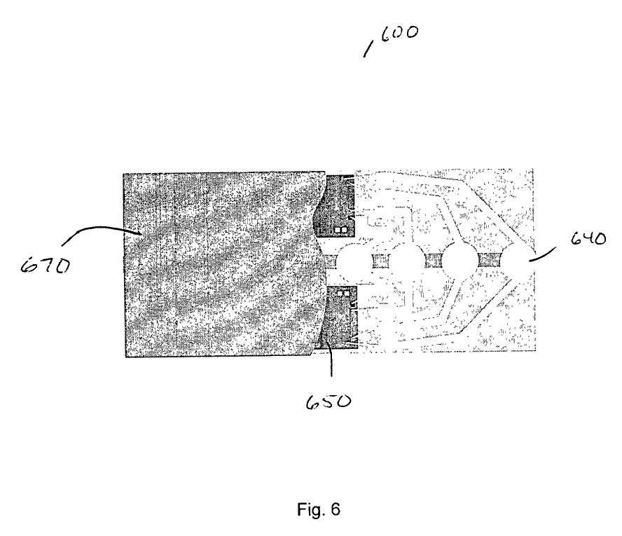

FIG. 6 illustrates the completed substrate 600 being molded or cast with a liquid compound 670. The molding or encapsulation 670 covers at least a portion of at least one side of the substrate, even though FIG. 6 shows the molding or encapsulation 670 covering the entire substrate 600 and die 650. Therefore, in FIG. 6, the molding 670 is partially cutaway for better illustration of the process. The molding 670 protects the die 650 and provides a finished package. As can be seen, it is important to have the vias 640 filled or blocked before this step to contain the compound.

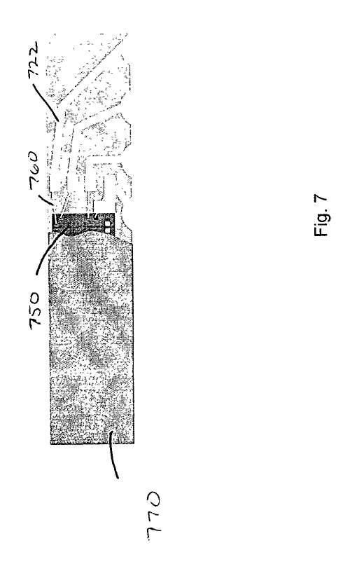

FIG. 7 illustrates the molded package after singulation 700. Singulation is the process of separating the individual parts after the complete substrate is molded. FIG. 7 is a view showing the molding 770 cut away exposing the die 750, wirebond 760 and metal lead lines 722. Singulation may be performed with a saw to give a very precise package edge. Testing can be done before or after singulation depending on the way adjacent packages are interconnected.

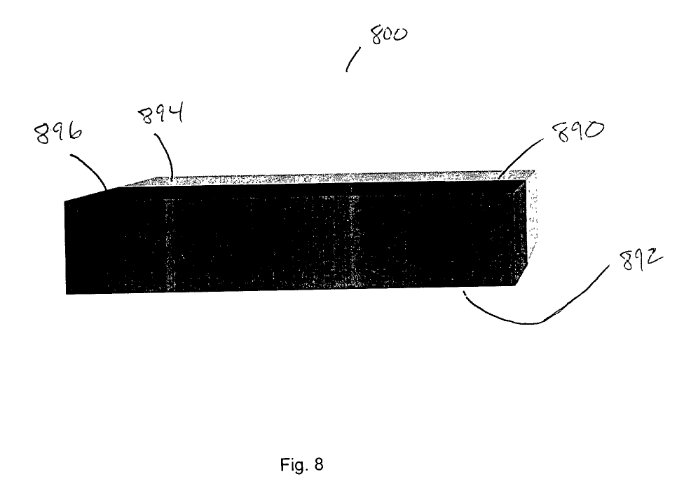

FIG. 8 illustrates a completed z-axis package 800 after processing. In FIG. 8, a top plane 890 is shown. Opposite the top plane 890 is the mounting plane 892 which is formed by the substrate 894 and encapsulation 896 applied to at least a portion of at least one side of the substrate 895. As described with reference to FIG. 6, the molding or encapsulation 896 covers at least a portion of at least one side of the substrate, even though FIG. 8 shows the molding or encapsulation 896 covering the entire substrate 894 600 and die (not shown).

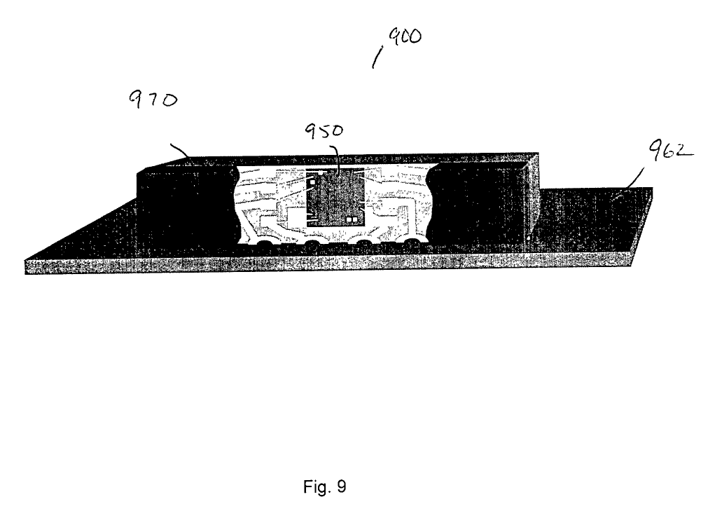

FIG. 9 illustrates the final z-axis package/circuit board combination 900 according to the present invention. In FIG. 9, the z-axis package 900 according to the present invention is shown located on an x-y platform, such as a larger printed circuit board substrate 962. In FIG. 9, the encapsulation 970 is shown partially cut away to clarify the concept. As described elsewhere, the die 950 may be a sensor. For example, the die 950 may be a magnetic sensor die such as a magnetoresistive sensor. Magnetoresistive sensor dies include anisotropic magnetoresistive (MR) sensor dies and giant magnetoresistive (GMR) sensor dies. Such devices lend themselves to applications in detecting magnetic anomalies such as ferrous metals and for magnetic compassing. Further, additional signal conditioning may be provided on the z-axis package and/or on the printed circuit board substrate 962. However, those skilled in the will recognize that the present invention is not meant to be limited to any particular type of sensor and that other sensors may be utilized without departing from the scope of the present invention.

Further, printed circuit board substrate 962 may include devices, such as multi-axis sensors, which may be used in conjunction with the device implemented in the z-axis package 900. Nevertheless, those skilled in the art will recognize that the device in the z-axis package 900 according to the present invention may be used independently and irrespective of devices on the printed circuit board substrate 962.

As can be seen from the above description of the process for making a z-axis package according to the present invention, the z-axis package itself can be assembled entirely using automated equipment. This makes it very cost effective. Furthermore, the package can be attached to the next level of interconnect (e.g., motherboard) using standard surface mount assembly equipment which increases the throughput and quality of the final assembly.

The z-axis package according to the present invention is built using a low cost laminate or ceramic substrate that is simultaneously wirebondable, wets easily with solder and is entirely non-magnetic. Because the z-axis package according to the present invention is built flat, conventional automated package equipment may be used. The use of via filling and sawing creates a z-axis package from a flat package with highly solderable leads

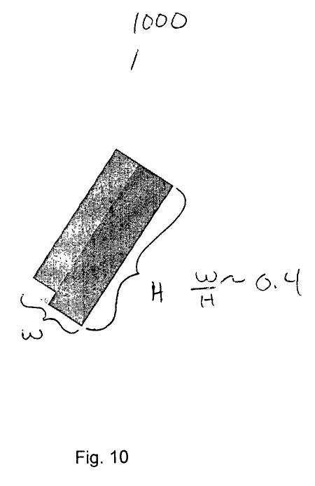

Another separate aspect of the z-axis package according to the present invention is that the package may achieve surface mounting stability by having a width/height ratio that is substantially equal to one, i.e., the height of the z-axis package is not substantially greater than the width of the z-axis package so as not to render the z-axis package difficult to maintain in its intended orientation with the die orthogonal to the mounting surface. FIG. 10 illustrates a z-axis package having a width/height ratio that is substantially less than one 1000 (the width/height ratio in FIG. 10 is approximately 0.4). As can be seen with reference to FIG. 10, the z-axis substrate having a width/height ratio that is substantially less than one 1000 is inherently unstable. This means that this z-axis substrate 1000 is easily tipped over thereby making assembly difficult.

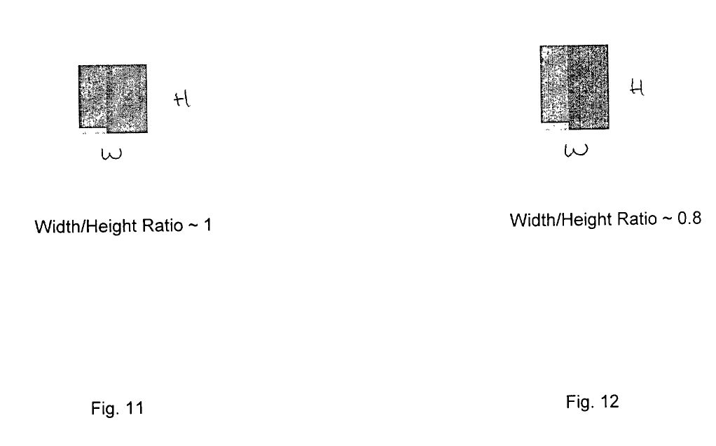

FIGS. 11 and 12 show the z-axis packages 1100, 1200 according to the present invention wherein the package has a width/height ratio that is substantially equal to one thereby lending stability to the package. The z-axis package 1100 of FIG. 11 is shown having a width/height ratio of approximately one. The z-axis package 1200 of FIG. 12 is shown having a width/height ratio of approximately 0.8. However, the width/height ratio could also be approximately 1.2 and still provide stability, albeit less. Nevertheless, those skilled in the art will recognize that the present invention is not meant to be limited to a particular width/height ratio, but rather the width/height ration is selected to be substantially one so as to render the z-axis package stable.

Furthermore, the system also includes a method of attachment that helps to maintains precise orthogonality of the package when mounted to an x-y platform, e.g., a circuit board. One means of attachment is solder paste and reflow. FIG. 13 illustrates a package 1300 having solderable terminals 1310 offset from package center 1312 and adjacent the package encapsulation material 1314.

FIG. 14 is an illustration of the attachment of the conventional package 1400. When the package 1400 is attached to x-y platform 1420 with conventional solder terminals (i.e., the offset solderable terminal 1310 of FIG. 13), the package can tilt a few degrees 1430 and disturb orthogonality of the vertical axis as illustrated in FIG. 14.

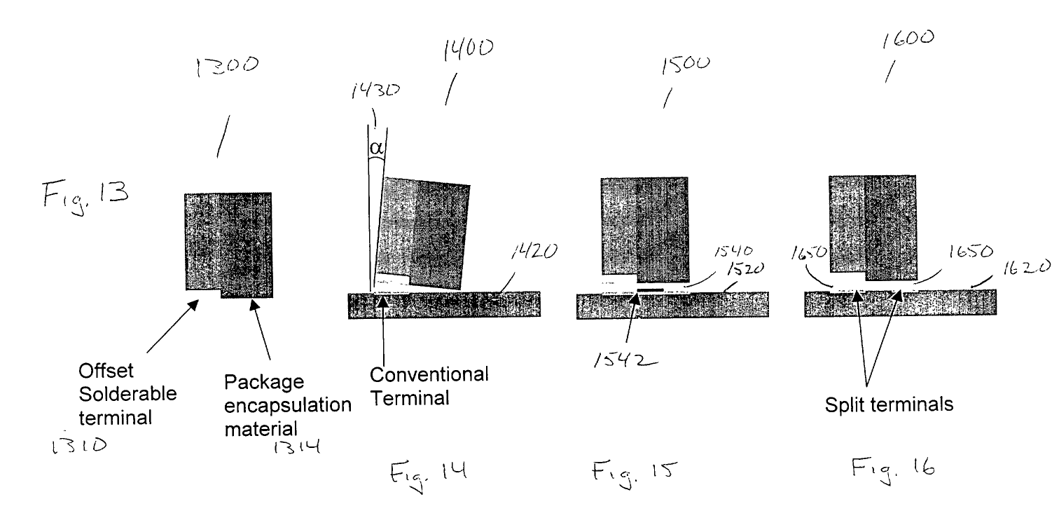

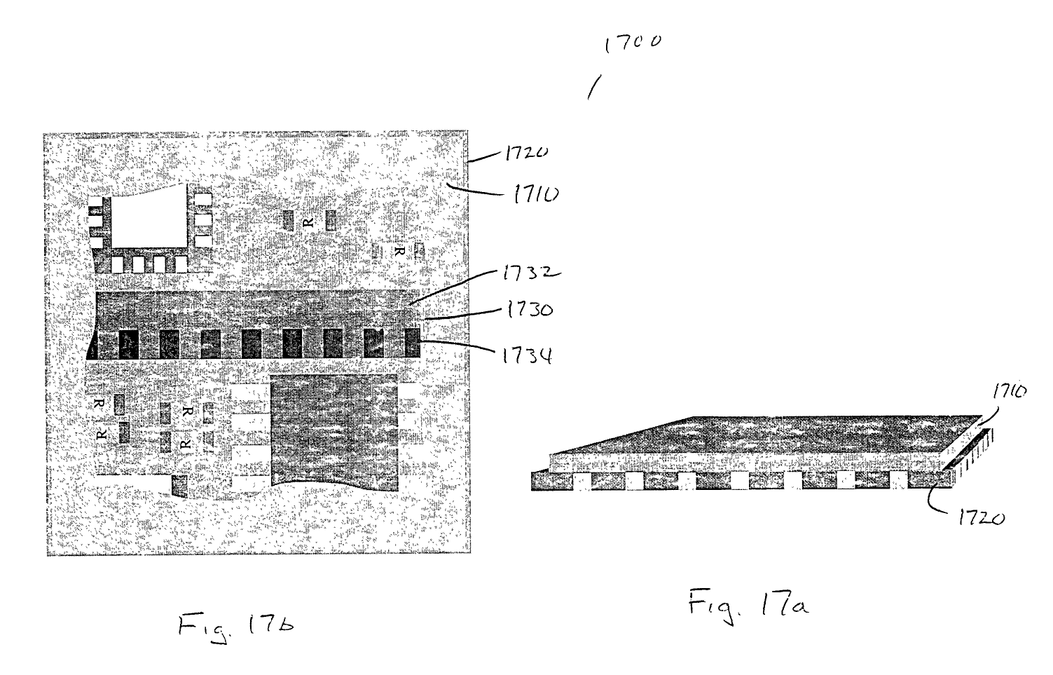

According to the present invention, the package is provided with an easily attainable orthogonality of the vertical axis. FIGS. 15-16 illustrate z-axis packages 1500, 1600 according to the present invention with defined extended 1540 or split terminals 1650 disposed on the x-y platform 1520, 1620 to act as leveling support structure during soldering. Extended terminals 1540 are continuous metal pad that are separated with soldermask 1542 as shown in FIG. 15. Split terminals 1650 are physically separate metal pads as shown in FIG. 16. In either case the result is two separate solder masses that are formed during solder reflow and which maintain package orthogonality. The choice between these topologies is selected to optimize substrate routing.

FIGS. 17a-b illustrate a module using the z-axis package 1700 according to the present invention. In FIG. 17a, the module using the z-axis package is shown encapsulated 1710 on a circuit board 1720. In FIG. 17b, a top view of the module using the z-axis package is shown with the encapsulation 1710 cut away. The z-axis package 1730 includes a mounting surface plane (not shown) formed by a substrate 1734 and encapsulation 1732 applied to at least a portion of at least one side of the substrate 1734. The mounting surface of the z-axis package makes contact with a circuit board 1720. The mounting surface plane is orthogonal to the plane of the substrate 1734. The substrate 1734 includes at least one die (not shown) coupled to the substrate 1734 orthogonal to the mounting surface plane and the circuit board 1720. The circuit board 1720 has at least one electronic device 1740 disposed thereon. The at least one electronic device 1740 and the z-axis package 1730 are encapsulated to form a single module with the circuit board 1720.

Accordingly, a z-axis package is provided for an electronic device that is inexpensive to manufacture and which can be assembled with automated surface mount equipment by the end user. The planar interconnection on a standard component (bonding pads on a silicon die for example) is redistributed to an orthogonal interconnection scheme in the package. The z-axis package according to the present invention may achieve surface mounting stability by having a width/height ratio that is substantially one. Precise orthogonality of the package may be achieved using defined extended or split terminals to act as leveling support structure during soldering.

The foregoing description of the exemplary embodiment of the invention has been presented for the purposes of illustration and description. It is not intended to be exhaustive or to limit the invention to the precise form disclosed. Many modifications and variations are possible in light of the above teaching. It is intended that the scope of the invention be limited not with this detailed description, but rather by the claims appended hereto.

What is claimed is:

1. A method for forming a z-axis electronic device package, comprising:
filling via holes in a substrate;
attaching at least one die to the substrate;
providing encapsulation to at least a portion of at least one side of the substrate; and
processing the substrate to form individual z-axis device packages having edge signal contacts at the via holes at a connection side of the z-axis package for providing connections to an x-y platform.

2. The method of claim 1 wherein the attaching at least one die comprises attaching a sensor device to the substrate.

3. The method of claim 2 wherein the attaching a sensor device to the substrate further comprises attaching a magnetoresistive sensor to the substrate.

4. The method of claim 3 wherein the attaching a magnetoresistive sensor to the substrate further comprises attaching an anisotropic magnetoresistive sensor to the substrate.

5. The method of claim 3 wherein the attaching a magnetoresistive sensor to the substrate further comprises attaching a giant magnetoresistive sensor to the substrate.

6. The method of claim 1 wherein the attaching at least one die to the substrate further comprises coupling the at least one die to metal lead line patterns on the substrate.

7. The method of claim 6 wherein the coupling the at least one die to metal lead line patterns on the substrate further comprises wirebonding the at least one die to the metal lead line patterns on the substrate.

8. The method of claim 6 further comprising soldering the metal lead line patterns to a higher-level printed circuit board assembly that forms a plane orthogonal to the plane of the z-axis package.

9. The method of claim 1 wherein the attaching at least one die to the substrate further comprises using a flip chip method to attached the die to the substrate.

10. The method of claim 1 wherein the filling of the via holes comprises filling the vias holes with solder.

11. The method of claim 1 wherein the processing the substrate to form individual z-axis device packages further comprises singulating the substrate into individual z-axis packages.

12. The method of claim 1 wherein the processing the substrate to form individual z-axis device packages further comprises forming individual z-axis packages having a width/height ratio that is selected to be substantially equal to one, the width/height ratio of substantially one lending stability to the package.

13. The method of claim 1 wherein the substrate consists essentially of a non-magnetic material.

14. A z-axis electronic device package, comprising a mounting surface plane formed by a substrate and encapsulation applied to at least a portion of at least one side of the substrate, the mounting surface including connections from the substrate, the connections being formed in the mounting surface plane, the mounting surface plane being orthogonal to a plane of the substrate, the substrate including at least one die coupled to the substrate orthogonal to the mounting surface plane.

15. The z-axis electronic device package of claim 14 wherein the at least one die comprises a sensor device.

16. The z-axis electronic device package of claim 15 wherein the sensor device further comprises a magnetoresistive sensor.

17. The z-axis electronic device package of claim 16 wherein the magnetoresistive sensor further comprises an anisotropic magnetoresistive sensor.

18. The z-axis electronic device package of claim 16 wherein the magnetoresistive sensor further comprises a giant magnetoresistive sensor.

19. The z-axis electronic device package of claim 14 wherein the at least one die is coupled to metal lead line patterns on the substrate.

20. The z-axis electronic device package of claim 19 wherein the at least one die is coupled to metal lead line patterns on the substrate by wirebonds.

21. The z-axis electronic device package of claim 14 wherein the substrate and encapsulation form a device having a width/height ratio that is selected to be substantially equal to one, the width/height ratio of substantially one providing stability to the package.

22. The z-axis electronic device package of claim 14 wherein the substrate consists essentially of a non-magnetic material.

23. The z-axis electronic device package of claim 14 wherein the mounting surface plane has a width that is substantially equal to the height of the substrate.

24. A z-axis electronic device package, comprising a mounting surface plane formed by a substrate and encapsulation applied to at least a portion of at least one side of the substrate, the mounting surface being coupled to defined extended terminals for providing a leveling support structure during soldering.

25. The z-axis electronic device package of claim 24 wherein the defined extended terminals further comprise a continuous metal pad with two ends being separated with a soldermask.

26. A z-axis electronic device package, comprising a mounting surface plane formed by a substrate and encapsulation applied to at least a portion of at least one side of the substrate, the mounting surface being coupled to split terminals for providing a leveling support structure during soldering.

27. The z-axis electronic device package of claim 26 wherein the split terminals further comprise separate metal pads.

28. A method for forming an electronic device package, comprising:
filling via holes in a substrate;
attaching at least one die to the substrate;
providing encapsulation to at least a portion of at least one side of the substrate; and
processing the substrate to form at least one individual z-axis device package having edge signal contacts at the via holes at a connection side of the z-axis package; and
mounting the z-axis device package to a circuit board forming an x-y plane.

29. The method of claim 28 wherein the attaching at least one die comprises attaching a sensor device to the substrate.

30. The method of claim 28 wherein the processing the substrate to form individual z-axis device packages further comprises forming individual z-axis packages having a width/height ratio that is selected to be substantially equal to one, the width/height ratio of substantially one providing stability to the package.

31. The method of claim 28 wherein the mounting of the z-axis package further comprises forming defined extended terminals on the x-y plane for providing a leveling support structure during mounting of the z-axis package to the x-y plane.

32. The method of claim 31 wherein the forming defined extended terminals further comprises forming a continuous metal pad with two ends being separated with a soldermask to form the extended terminals.

33. The method of claim 28 wherein the mounting of the z-axis package further comprises forming split terminals on the x-y plane for providing a leveling support structure during mounting of the z-axis package to the x-y plane.

34. The method of claim 33 wherein the forming split terminals further comprises forming separate metal pads for the split terminals.

35. The method of claim 28 wherein the processing the substrate to form individual z-axis device packages further comprises singulating the substrate into individual z-axis packages.

36. The method of claim 28 wherein the filling of the via holes comprises filling the vias holes with solder.

37. The method of claim 28 wherein the substrate consists essentially of a non-magnetic material.

38. An electronic device package, comprising:
a z-axis electronic package, the z-axis package including a mounting surface plane formed by a substrate and encapsulation applied to at least a portion of at least one side of the substrate, the mounting surface including connections from the substrate, the connections being formed in the mounting surface plane, the mounting surface plane being orthogonal to a plane of the substrate, the substrate including at least one die coupled to the substrate orthogonal to the mounting surface plane; and
a circuit board having at least one electronic device thereon, wherein the z-axis electronic package is mounted to the circuit board at the mounting surface plane of the z-axis package for maintaining the at least one die orthogonal to a plane formed by the circuit board.

39. The electronic device package of claim 38 wherein the at least one die comprises a sensor device.

40. The electronic device package of claim 38 wherein the z-axis electronic package has a width/height ratio that is selected to be substantially equal to one, the width/height ratio of substantially one providing stability to the package.

41. The electronic device package of claim 38 further comprising defined extended terminals disposed on the circuit board for providing a leveling support structure during mounting of the z-axis electronic package to the circuit board.

42. The electronic device package of claim 41 wherein the defined extended terminals further comprise a continuous metal pad with two ends being separated with a soldermask.

43. The electronic device package of claim 38 further comprises split terminals disposed on the circuit board for providing a leveling support structure during soldering of the z-axis electronic package to the circuit board.

44. The electronic device package of claim 43 wherein the split terminals further comprise separate metal pads.

45. The electronic device package of claim 38 wherein the substrate consists essentially of a non-magnetic material.

46. The electronic device package of claim 38 wherein the mounting surface plane has a width that is substantially equal to the height of the substrate.

47. A method for forming a z-axis electronic device package, comprising:
filling via holes in a substrate;
attaching at least one die to the substrate;
providing encapsulation to at least a portion of at least one side of the substrate; and
processing the substrate to form individual z-axis device packages having a width/height ratio that is selected to be substantially equal to one and having edge signal contacts at the via holes at a connection side of the z-axis package for providing connections to an x-y platform, wherein the width/height ratio of substantially one provides stability to the package.

48. A z-axis electronic device package, comprising a mounting surface plane formed by a substrate and encapsulation applied to at least a portion of at least one side of the substrate, the mounting surface including connections from the substrate, the connections being formed in the mounting surface plane, the mounting surface plane being orthogonal to a plane of the substrate, the substrate including at least one die coupled to the substrate orthogonal to the mounting surface plane, wherein the substrate and encapsulation form a device having a width/height ratio that is selected to be substantially equal to one, the width/height ratio of substantially one providing stability to the package.
